(19) United States
(12) Patent Application Publication
(10) Pub. No.: US 2023/0287196 A1
(43) Pub. Date: Sep. 14, 2023

(54) POWER TOOLS AND OTHER DEVICES INCLUDING GRAPHENE POLYMERIC HOUSING STRUCTURES

(71) Applicant: MILWAUKEE ELECTRIC TOOL CORPORATION, Brookfield, WI (US)

(72) Inventor: Donald J. Truettner, Waukesha, WI (US)

(21) Appl. No.: 18/181,122

(22) Filed: Mar. 9, 2023

Related U.S. Application Data
(60) Provisional application No. 63/319,000, filed on Mar. 11, 2022.

(51) Int. Cl. C08K 3/04; B25F 5/02; H01M 50/222; H01M 50/227; H01M 50/229; H01M 50/233; H05K 9/00

(52) U.S. Cl. CPC C08K 3/042; B25F 5/02; H01M 50/222; H01M 50/227; H01M 50/229; H01M 50/233; H05K 9/0083; H05K 9/0079; C08K 2201/001

(57) ABSTRACT

Devices, such as power tools, outdoor power equipment, lighting devices, test and measurement devices, battery packs, battery pack chargers, power supply devices, modular storage units, etc., include housing structures or other components of the devices made with graphene and/or a graphene polymeric material. The graphene polymeric materials include graphene and a polymer. The graphene polymeric materials are particularly advantageous for electromagnetic shielding purposes. Specific components of the graphene polymeric material may be selected based on their electromagnetic (“EM”) shielding effects (e.g., attenuation, reflection, and/or absorption of radiated emissions) and electrostatic discharge (“ESD”) shielding effects (e.g., dissipation of excess electrical charge and prevention of electrostatic charge accumulation).

### RELATED APPLICATIONS

This application claims priority to U.S. Provisional Patent Application No. 63/319,000, filed on Mar. 11, 2022, the entire content of which is hereby incorporated by reference.

### BACKGROUND

Embodiments described herein provide power tools and other related devices.

### SUMMARY

Embodiments described herein relate to devices, such as power tools, outdoor power equipment, lighting devices, test and measurement devices, battery packs, battery pack chargers, power supply devices, modular storage units, etc., that include housing structures or other components of the devices made with graphene and/or a graphene polymeric material.

The graphene polymeric materials of the present disclosure comprise graphene and a polymer. The graphene polymeric materials described herein are particularly advantageous for electromagnetic shielding purposes, and thus when using these materials in the devices of the present disclosure, specific components of the graphene polymeric material may be selected based on their electromagnetic (“EM”) shielding effects (e.g., attenuation, reflection, and/or absorption of radiated emissions) and electrostatic discharge (“ESD”) shielding effects (e.g., dissipation of excess electrical charge and prevention of electrostatic charge accumulation).

Graphene polymeric materials described herein include graphene and a polymer.

Methods described herein of forming an article of manufacture from a graphene polymeric material include providing a graphene polymeric material comprising graphene and a polymer, and forming the article of manufacture from the graphene polymeric material.

Devices described herein include a housing that includes a graphene polymeric material. The graphene polymeric material incudes graphene and a polymer.

Before any embodiments are explained in detail, it is to be understood that the embodiments are not limited in their application to the details of the configuration and arrangement of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

Relative terminology, such as, for example, “about,” “approximately,” “substantially,” etc., used in connection with a quantity or condition would be understood by those of ordinary skill to be inclusive of the stated value and has the meaning dictated by the context (e.g., the term includes at least the degree of error associated with the measurement accuracy, tolerances [e.g., manufacturing, assembly, use, etc.] associated with the particular value, etc.). Such terminology should also be considered as disclosing the range defined by the absolute values of the two endpoints. For example, the expression “from about 2 to about 4” also discloses the range “from 2 to 4”. The relative terminology may refer to plus or minus a percentage (e.g., 1%, 5%, 10%, or more) of an indicated value.

It should be understood that although certain drawings illustrate hardware and software located within particular devices, these depictions are for illustrative purposes only. Functionality described herein as being performed by one component may be performed by multiple components in a distributed manner. Likewise, functionality performed by multiple components may be consolidated and performed by a single component. In some embodiments, the illustrated components may be combined or divided into separate software, firmware and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable communication links. Similarly, a component described as performing particular functionality may also perform additional functionality not described herein. For example, a device or structure that is “configured” in a certain way is configured in at least that way but may also be configured in ways that are not explicitly listed.

Other aspects of the embodiments will become apparent by consideration of the detailed description and accompanying drawings.

### BRIEF DESCRIPTION OF THE DRAWINGS

FIG. 1 illustrates a power tool according to embodiments described herein.

FIG. 2 illustrates outdoor power equipment according to embodiments described herein.

FIG. 3 illustrates a lighting device according to embodiments described herein.

FIG. 4 illustrates a test and measurement device according to embodiments described herein.

FIG. 5 illustrates a battery pack according to embodiments described herein.

FIG. 6 illustrates a battery pack charger according to embodiments described herein.

FIG. 7 illustrates a power supply device according to embodiments described herein.

FIG. 8. illustrates a modular storage device according to embodiments described herein.

FIG. 9 illustrates a control system for a device according to embodiments described herein.

FIG. 10 illustrates a radiated emissions signature for a device that does not include a graphene polymer housing shield.

FIG. 11 illustrates a radiated emissions signature for a device that does include a graphene polymer housing shield.

### DETAILED DESCRIPTION

Embodiments described herein generally relate to devices, such as power tools, outdoor power equipment, lighting devices, test and measurement devices, battery packs, battery pack chargers, power supply devices, modular storage units, etc., that include housing structures or other components of the devices made with graphene and/or a graphene polymeric material.

Graphene polymeric materials of the present disclosure comprise graphene and a polymer. The graphene polymeric materials described herein are particularly advantageous for electromagnetic shielding purposes, and thus when using these materials in the devices of the present disclosure, specific components of the graphene polymeric material may be selected based on their electromagnetic (“EM”) shielding effects (e.g., attenuation, reflection, and/or absorption of radiated emissions) and electrostatic discharge (“ESD”) shielding effects (e.g., dissipation of excess electrical charge, and prevention of electrostatic charge accumulation).

The term “graphene” may refer to pure or relatively pure carbon in the form of a sheet, which is one atom in thickness (i.e., a monolayer sheet of carbon), or comprising multiple layers (i.e., multilayer carbon sheets) having a plurality of interconnected hexagonal cells of carbon atoms, most of which are present in sp² hybridized state, and which forms a honeycomb like crystalline lattice structure.

The graphene polymeric materials of the present disclosure may comprise varying amounts of graphene. The graphene polymeric material may comprise 0.1 weight % (wt %) graphene to 75 wt % graphene. In various instances, the graphene polymeric material may comprise 0.1 wt % graphene to 70 wt % graphene; 0.1 wt % graphene to 65 wt % graphene; 0.5 wt % graphene to 60 wt % graphene; 0.5 wt % graphene to 55 wt % graphene; 1 wt % graphene to 55 wt % graphene; 1.5 wt % graphene to 50 wt % graphene; 2 wt % graphene to 50 wt % graphene; 2.5 wt % graphene to 45 wt % graphene; 5 wt % graphene to 45 wt % graphene; or 15 wt % graphene to 40 wt %. In various instances, the graphene polymeric material may comprise no greater than 75 wt % graphene; no greater than 70 wt % graphene; no greater than 65 wt % graphene; no greater than 60 wt % graphene; no greater than 55 wt % graphene; no greater than 50 wt % graphene; no greater than 45 wt % graphene; no greater than 40 wt % graphene; no greater than 35 wt % graphene; no greater than 30 wt % graphene; no greater than 25 wt % graphene; no greater than 20 wt % graphene; no greater than 15 wt % graphene; no greater than 10 wt % graphene; no greater than 5 wt % graphene; no greater than 2.5 wt % graphene; no greater than 2 wt % graphene; no greater than 1.5 wt % graphene; no greater than 1 wt % graphene; or no greater than 0.5 wt % graphene. In various instances, the graphene polymeric material may comprise no less than 0.5 wt % graphene; no less than 1 wt % graphene; no less than 1.5 wt % graphene; no less than 2 wt %; no less than 2.5 wt % graphene; no less than 5 wt % graphene; no less than 10 wt % graphene; no less than 15 wt % graphene; no less than 20 wt % graphene; no less than 25 wt % graphene; no less than 30 wt % graphene; no less than 35 wt % graphene; no less than 40 wt % graphene; no less than 45 wt % graphene; no less than 50 wt % graphene; no less than 55 wt % graphene; no less than 60 wt % graphene; no less than 65 wt % graphene; no less than 70 wt % graphene; or no less than 75 wt % graphene.

The term “polymer” may encompass homopolymers and copolymers. The term “copolymer” may generically refer to a polymeric structure that has two or more monomers polymerized with one another. The term “homopolymer” may refer to a polymer formed of a single repeating monomer.

In various instances, the polymer for the graphene polymeric material may be selected from: olefin homopolymers and copolymers, such as acrylonitrile-butadiene-styrene (“ABS”) and styrene-butadiene-alkyl methacrylate (“SBM”) homopolymers and copolymers; polyethylene, polypropylene, polybutadiene and polybutylene; acrylic homopolymers and copolymers and polyalkyl (meth)acrylates, such as polymethyl methacrylate; homopolyamides and copolyamides; polycarbonates; polyesters, including polyethylene terephthalate and polybutylene terephthalate; polyethers, such as polyphenylene ether, polyoxymethylene, polyoxyethylene or polyethylene glycol and polyoxypropylene; polystyrene; styrene/maleic anhydride copolymers; polyvinyl chloride; fluoropolymers, such as polyvinylidene fluoride, polytetrafluoroethylene and polychlorotrifluoroethylene; natural or synthetic rubbers; thermoplastic polyurethanes (“TPU”); polyaryletherketones (“PAEK”), such as polyetheretherketone (“PEEK”) and polyetherketoneketone (“PEKK”); polyetherimide; polysulphone; polyphenylene sulphide; cellulose acetate; polyvinyl acetate; and combinations thereof. In various instances, the polymer for the graphene polymeric material may comprise a polyethylene e.g., high density polyethylene (HDPE).

In various instances, the polymer is a thermoplastic polymer. The term “thermoplastic polymer” is understood, in the context of the present disclosure, to be a polymer that melts when it is heated, and which can be formed and reformed in the melt state. the thermoplastic polymer comprises at least one polymer selected from the group consisting of polyvinyl chloride, polycarbonate, acrylonitrile butadiene styrene, polyamide, polypropylene, and high-density polyethylene.

The thermoplastic polymer may be a thermoplastic polyurethane derived from (a) a polyisocyanate component, (b) a polyol component, and (c) an optional chain extender component. For thermoplastic polyurethanes derived from (a) a polyisocyanate component, (b) a polyol component, and (c) an optional chain extender component, suitable polyisocyanates include aromatic diisocyanates, aliphatic diisocyanates, or combinations thereof.

In some embodiments, the polyisocyanate component includes one or more aromatic diisocyanates. In some embodiments, the polyisocyanate component is essentially free of, or even completely free of, aliphatic diisocyanates. In other embodiments, the polyisocyanate component includes one or more aliphatic diisocyanates. In some embodiments, the polyisocyanate component is essentially free of, or even completely free of, aromatic diisocyanates. Examples of polyisocyanates used according to embodiments of the disclosure include aromatic diisocyanates such as 4,4′-methylenebis(phenyl isocyanate) (“MDI”), m-xylene diisocyanate (“XDI”), phenylene-1,4-diisocyanate, naphthalene-1,5-diisocyanate, and toluene diisocyanate (“TDI”); as well as aliphatic diisocyanates such as isophorone diisocyanate (“IPDI”), 1,4-cyclohexyl diisocyanate (“CHDI”), decane-1,10-diisocyanate, lysine diisocyanate (“LDI”), 1,4-butane diisocyanate (“BDI”), isophorone diisocyanate (“PDI”), 3,3′-dimethyl-4,4′-biphenylene diisocyanate (“TODI”), 1,5-naphthalene diisocyanate (“NDI”), and dicyclohexylmethane-4,4′-diisocyanate (“H12MDI”). Mixtures of two or more polyisocyanates may be used.

For thermoplastic polyurethanes derived from (a) a polyisocyanate component, (b) a polyol component, and (c) an optional chain extender component, suitable polyols, which may also be described as hydroxyl terminated intermediates, when present, may include one or more hydroxyl terminated polyesters, one or more hydroxyl terminated polyethers, one or more hydroxyl terminated polycarbonates, one or more hydroxyl terminated polysiloxanes, or mixtures thereof.

The polyester intermediates may be produced by an esterification reaction of one or more glycols with one or more dicarboxylic acids or anhydrides or by transesterification reaction, i.e., the reaction of one or more glycols with esters of dicarboxylic acids. Suitable polyester intermediates also include various lactones such as polycaprolactone typically made from ε-caprolactone and a bifunctional initiator such as diethylene glycol. The dicarboxylic acids of the desired polyester can be aliphatic, cycloaliphatic, aromatic, or combinations thereof. Suitable dicarboxylic acids which may be used alone or in mixtures generally have a total of from 4 to 15 carbon atoms and include: succinic, glutaric, adipic, pimelic, suberic, azelaic, sebacic, dodecanedioic, isophthalic, terephthalic, cyclohexane dicarboxylic, and the like. Anhydrides of the above dicarboxylic acids such as phthalic anhydride, tetrahydrophthalic anhydride, or the like, can also be used. The glycols which are reacted to form a desirable polyester intermediate can be aliphatic, aromatic, or combinations thereof, including any of the glycols described above in the chain extender section, and have a total of from 2 to 20, or from 2 to 12 carbon atoms. Suitable examples include ethylene glycol, 1,2-propanediol, 1,3-propanediol, 1,3-butanediol, 1,4-butanediol, 1,5-pentanediol, 1,6-hexanediol, 2,2-dimethyl-1,3-propanediol, 1,4-cyclohexanedimethanol, decamethylene glycol, dodecamethylene glycol, and mixtures thereof. The polyol component may also include one or more polycaprolactone polyester polyols. Polycaprolactone polyester polyols according to embodiments of the disclosed subject matter can include polyester diols derived from caprolactone monomers. The polycaprolactone polyester polyols can be terminated by primary hydroxyl groups. Suitable polycaprolactone polyester polyols may be made from ε-caprolactone and a bifunctional initiator such as diethylene glycol, 1,4-butanediol, or any of the other glycols and/or diols listed herein. In some embodiments, the polycaprolactone polyester polyols are linear polyester diols derived from caprolactone monomers.

Suitable hydroxyl terminated polyether intermediates include polyether polyols derived from a diol or polyol having a total of from 2 to 15 carbon atoms, in some embodiments an alkyl diol or glycol which is reacted with an ether comprising an alkylene oxide having from 2 to 6 carbon atoms, typically ethylene oxide or propylene oxide or mixtures thereof. For example, hydroxyl functionalized polyether can be produced by first reacting propylene glycol with propylene oxide, followed by the subsequent reaction with ethylene oxide. Useful commercial polyether polyols include poly(ethylene glycol) comprising ethylene oxide reacted with ethylene glycol, poly(propylene glycol) comprising propylene oxide reacted with propylene glycol, poly(tetramethylene ether glycol) comprising water reacted with tetrahydrofuran which can also be described as polymerized tetrahydrofuran, and which is commonly referred to as PTMEG.

Suitable hydroxyl terminated polycarbonates include those prepared by reacting a glycol with a carbonate. Such polycarbonates are linear and have terminal hydroxyl groups with essential exclusion of other terminal groups. The essential reactants are glycols and carbonates. Suitable glycols are selected from aliphatic diols containing 4 to 40, preferably 4 to 12 carbon atoms, and from polyoxyalkylene glycols containing 2 to 20 alkoxy groups per molecule with each alkoxy group containing 2 to 4 carbon atoms. Suitable diols include aliphatic diols containing 4 to 12 carbon atoms such as 1,4-butanediol, 1,5-pentanediol, neopentyl glycol, 1,6-hexanediol, 2,2,4-trimethyl-1,6-hexanediol, 1,10-decanediol, hydrogenated dilinoleylglycol, hydrogenated dioleylglycol, 3-methyl-1,5-pentanediol; and cycloaliphatic diols such as 1,3-cyclohexanediol, 1,4-dimethylolcyclohexane, 1,4-cyclohexanediol-, 1,3-dimethylolcyclohexane-, 1,4-endomethylene-2-hydroxy-5-hydroxymethyl cyclohexane, and polyalkylene glycols. The diols used in the reaction may be a single diol or a mixture of diols depending on the properties desired in the finished product. Polycarbonate intermediates which are hydroxyl terminated are generally those known to the art and in the literature. Suitable carbonates are selected from alkylene carbonates composed of a 5 to 7-membered ring. Suitable carbonates for use herein include ethylene carbonate, trimethylene carbonate, tetramethylene carbonate, 1,2-propylene carbonate, 1,2-butylene carbonate, 2,3-butylene carbonate, 1,2-ethylene carbonate, 1,3-pentylene carbonate, 1,4-pentylene carbonate, 2,3-pentylene carbonate, and 2,4-pentylene carbonate. Also, suitable herein are dialkylcarbonates, cycloaliphatic carbonates, and diarylcarbonates. The dialkylcarbonates can contain 2 to 5 carbon atoms in each alkyl group and specific examples thereof are diethylcarbonate and dipropylcarbonate. Cycloaliphatic carbonates, especially dicycloaliphatic carbonates, can contain 4 to 7 carbon atoms in each cyclic structure, and there can be one or two of such structures. When one group is cycloaliphatic, the other can be either alkyl or aryl. On the other hand, if one group is aryl, the other can be alkyl or cycloaliphatic. Examples of suitable diarylcarbonates, which can contain 6 to 20 carbon atoms in each aryl group, for instance, include diphenylcarbonate, ditolylcarbonate, and dinaphthylcarbonate.

Suitable polyether polyols also include polyamide adducts of an alkylene oxide and can include, for example, ethylenediamine adduct comprising the reaction product of ethylenediamine and propylene oxide, diethylenetriamine adduct comprising the reaction product of diethylenetriamine with propylene oxide, and similar polyamide type polyether polyols.

Suitable polysiloxane polyols include alpha-omega-hydroxyl or amine or carboxylic acid or thiol or epoxy terminated polysiloxanes. Examples include poly(dimethysiloxane) terminated with a hydroxyl or amine or carboxylic acid or thiol or epoxy group. In some embodiments, the polysiloxane polyols are hydroxyl terminated polysiloxanes. Polysiloxane polyols may be obtained by the dehydrogenation reaction between a polysiloxane hydride and an aliphatic polyhydric alcohol or polyoxyalkylene alcohol to introduce the alcoholic hydroxy groups onto the polysiloxane backbone. Suitable examples include alpha-omega-hydroxypropyl terminated poly(dimethysiloxane) and alpha-omega-amino propyl terminated poly(dimethysiloxane), both of which are commercially available materials. Further examples include copolymers of the poly(dimethysiloxane) materials with poly(alkylene oxide).

The polyol component, when present, may include poly(ethylene glycol), poly(tetramethylene ether glycol), poly(trimethylene oxide), ethylene oxide capped poly(propylene glycol), poly(butylene adipate), poly(ethylene adipate), poly(hexamethylene adipate), poly(tetramethylene-co-hexamethylene adipate), poly(3-methyl-1,5-pentamethylene adipate), polycaprolactone diol, poly(hexamethylene carbonate) glycol, poly(pentamethylene carbonate) glycol, poly(trimethylene carbonate) glycol, dimer fatty acid based polyester polyols, vegetable oil based polyols, or any combination thereof.

In some embodiments, the polyol component includes a polyether polyol, a polycarbonate polyol, a polycaprolactone polyol, or any combination thereof. In some embodiments, the polyol component includes a polyether polyol. In some embodiments, the polyol component is essentially free of or even completely free of polyester polyols.

For thermoplastic polyurethanes derived from (a) a polyisocyanate component, (b) a polyol component, and (c) an optional chain extender component, suitable chain extenders include relatively small polyhydroxy compounds, for example, lower aliphatic or short chain glycols having from 2 to 20, 2 to 12, or 2 to 10 carbon atoms.

Suitable examples of chain extender components include ethylene glycol, diethylene glycol, propylene glycol, dipropylene glycol, 1,4-butanediol (“BDO”), 1,6-hexanediol (“HDO”), 1,3-butanediol, 1,5-pentanediol, neopentylglycol, 1,4-cyclohexanedimethanol (“CHDM”), 2,2-bis[4-(2-hydroxyethoxy)] phenyl propane (“HEPP”), hexamethylenediol, heptanediol, nonanediol, dodecanediol, 3-methyl-1,5-pentanediol, ethylenediamine, butanediamine, hexamethylenediamine, and hydroxyethyl resorcinol (“HER”), and the like, as well as mixtures thereof.

The graphene polymeric material of the present disclosure may comprise varying amounts of polymer. The graphene polymeric material may comprise 35 wt % to 99.9 wt % polymer. In various instances, the graphene polymeric material may comprise 35 wt % polymer to 95 wt % polymer; 30 wt % polymer to 95 wt % polymer; 35 wt % polymer to 90 wt % polymer; 35 wt % polymer to 85 wt % polymer; 40 wt % polymer to 85 wt % polymer; 40 wt % polymer to 80 wt % polymer; 45 wt % polymer to 80 wt % polymer; or 45 wt % polymer to 75 wt % polymer. In various instances, the graphene polymeric material may comprise no greater than 95 wt % polymer; no greater than 85 wt % polymer; no greater than 75 wt % polymer; no greater than 65 wt % polymer; no greater than 55 wt % polymer; no greater than 45 wt % polymer; or no greater than no greater than 35 wt % polymer. In various instances, the graphene polymeric material may comprise no less than 35 wt % polymer; no less than 45 wt % polymer; no less than 55 wt % polymer; no less than 65 wt % polymer; no less than 75 wt % polymer; no less than 85 wt % polymer; or no less than 95 wt % polymer.

The graphene polymeric material as described herein may be present in various forms, which may depend on the material's intended use for the particular device and/or device's housing. In various instances the graphene polymeric material is present in a hard, for example substantially cylindrical, spherical, ovoid, rectangular or prismatic, form. The graphene polymeric material may be, for example, in the form of pellets.

When the graphene polymeric material is in pellet form, the average pellet size may range from 0.1 μm to 1000 μm. In various instances the average pellet size may range from 0.5 μm to 500 μm; 1 μm to 100 μm; or 1.5 μm to 50 μm.

The graphene polymeric materials described herein may be prepared using various techniques. In various instances, the method for preparing the graphene polymeric material may comprise mixing graphene (e.g., graphene powder) with a polymer, followed by heating the graphene/polymer mixture.

Embodiments of the present disclosure may be manufactured using or involving an injection molding method comprising injecting a graphene polymeric material according to the present disclosure into a mold and processing to create an injection molded article of manufacture. In some instances, the graphene polymeric materials of the present disclosure may be injection molded using a suitable injection molding device, generally known in the art. Injection molding may involve injecting the graphene polymeric material, molten by heat, into a mold, followed by cooling to produce a solidified, injection-molded article of manufacture.

In one or more embodiments, the injection molded article of manufacture may be in the form of a housing or a plating on a surface, wherein the graphene polymeric material functions as an electromagnetic (“EM”) shield that attenuates, reflects, and/or absorbs radiated emissions, or as an electrostatic discharge (“ESD”) shield that dissipates excess electrostatic charge and prevents electrostatic charge accumulation.

Examples of devices that can include the above-described graphene polymeric materials are provided below.

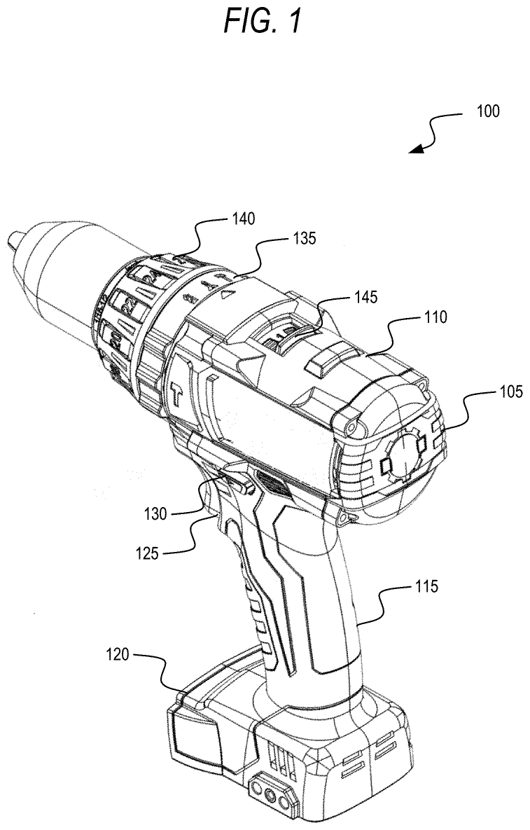

FIG. 1 illustrates a power tool 100 that includes a housing 105. The housing 105 includes a motor housing 110, a handle 115, and a power source (e.g., battery pack) receiving portion 120. The power tool 100 also includes a trigger 125, a forward/reverse switch 130, a mode selection input 135, a first or torque input 140, and a second or speed input 145. In the illustrated embodiment, the power tool 100 is a hammer drill. In other embodiments, the power tool 100 can be a different power tool. For example, the power tool 100 can be a drill driver, a right-angle drill, a magnetic drill, an impact driver, an impact wrench, a ratchet, a screwdriver, a screwgun, a rotary hammer, a cut-off saw, a core drill, a dust extractor, a sprayer, an auger, a sink machine, a drum machine, a crimper, a wire stripper, an electrical cutter, a fish tape, a knockout tool, a pump, a pipe threader, a rod cutter, a press tool, a threading tool, an expander tool, a copper or PVC cutter, a transfer pump, a laser level, a grinder, a band saw, a sander, a nibbler, a reciprocating saw, a hacksaw, a hoist, a mixer, a radio, a rivet tool, a heater, a circular saw, a jig saw, a table saw, a miter saw, an oscillating multitool, a nailer, a stapler, a panel saw, a planer, a router, a compressor, a vacuum cleaner, a wet/dry vacuum cleaner, a blower, a fan, a concrete vibrator, a vibratory screed, a breaker, a drain cleaner, etc. Each power tool 100 includes at least the housing 105 which includes graphene or a graphene polymeric material described herein.

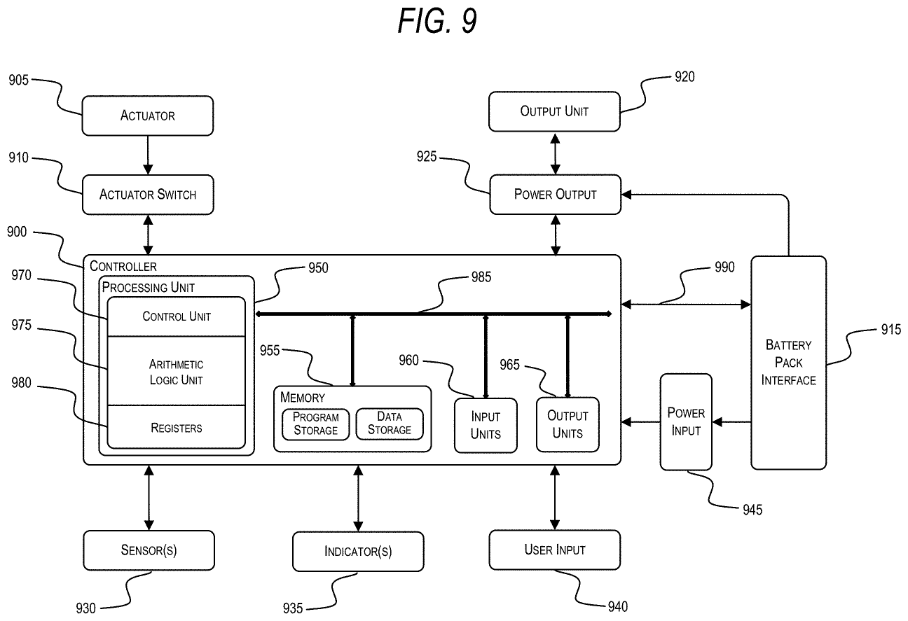

In some embodiments, the entire housing 105 includes (e.g., is made of or to include) graphene and/or a graphene polymeric material. In other embodiments, only a portion of the housing 105 includes (e.g., is made of or to include) graphene and/or a graphene polymeric material. For example, a portion of the housing 105 in proximity to electronics within the housing 105 (see, e.g., FIG. 9). For example, one or more of the motor housing 110, the handle 115, the power source receiving portion 120, includes (e.g., is made of or to include) graphene and/or a graphene polymeric material. In some embodiments, the trigger 125, the forward/reverse switch 130, the mode selection input 135, the first or torque input 140, and the second or speed input 145 includes (e.g., is made of or to include) graphene and/or a graphene polymeric material.

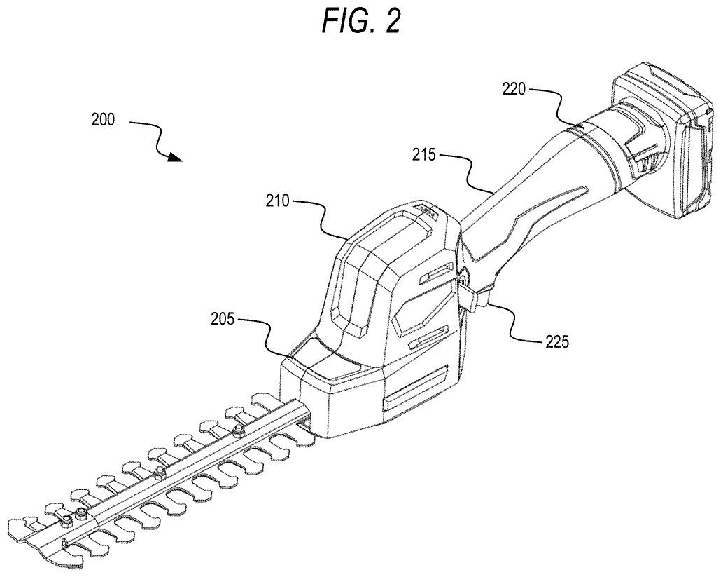

FIG. 2 illustrates a piece of outdoor power equipment 200. The outdoor power equipment includes a housing 205. The housing 205 includes a motor housing 210, a handle 215, and a power source (e.g., battery pack) receiving portion 220. The outdoor power equipment also includes a trigger 225. In the illustrated embodiment, the outdoor power equipment 200 is a trimmer. In other embodiments, the outdoor power equipment 200 can be a different piece of outdoor power equipment. For example, the outdoor power equipment 200 can be a blower, a lawn mower, a chainsaw, a hatchet saw, a sprayer, a string trimmer, etc. Each piece of outdoor power equipment 200 includes at least the housing 205 which includes graphene or a graphene polymeric material described herein.

In some embodiments, the entire housing 205 includes (e.g., is made of or to include) graphene and/or a graphene polymeric material. In other embodiments, only a portion of the housing 205 includes (e.g., is made of or to include) graphene and/or a graphene polymeric material. For example, a portion of the housing 205 in proximity to electronics within the housing 205 (see, e.g., FIG. 9). For example, one or more of the motor housing 210, the handle 215, the power source receiving portion 220, includes (e.g., is made of or to include) graphene and/or a graphene polymeric material. In some embodiments, the trigger 225 includes (e.g., is made of or to include) graphene and/or a graphene polymeric material.

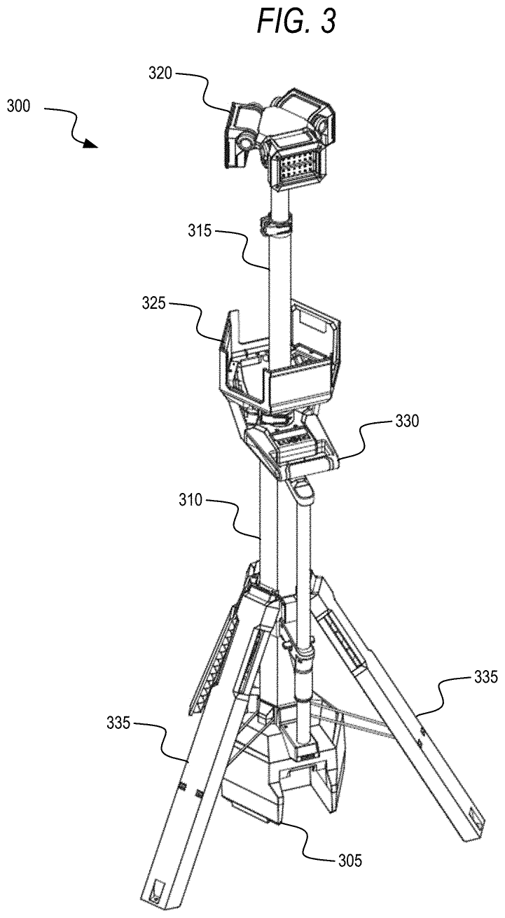

FIG. 3 illustrates a lighting device 300. The lighting device 300 includes a housing 305. The lighting device 300 also includes an outer stem 310 and an inner stem 315 for telescoping a lighting unit 320. A lighting unit housing 325 houses the lighting unit 320 when the lighting unit 320 is not extended. The lighting device 300 also includes a handle 330 and one or more legs 335 for stabilizing the lighting device 300. In the illustrated embodiment, the lighting device 300 is a tower light. In other embodiments, the lighting device 300 can be a different lighting device. For example, the lighting device 300 can be a headlamp, a search light, a site light, a detailing light, a flood light, a work light, an underbody light, etc. Each lighting device 300 includes at least the housing 305 which includes graphene or a graphene polymeric material described herein.

In some embodiments, the entire housing 305 includes (e.g., is made of or to include) graphene and/or a graphene polymeric material. In other embodiments, only a portion of the housing 305 includes (e.g., is made of or to include) graphene and/or a graphene polymeric material. For example, a portion of the housing 305 in proximity to electronics within the housing 305 (see, e.g., FIG. 9). In some embodiments, the outer stem 310, the inner stem 315, the lighting unit 320, the lighting unit housing 325, the handle 330, and the legs 335 include (e.g., is made of or to include) graphene and/or a graphene polymeric material.

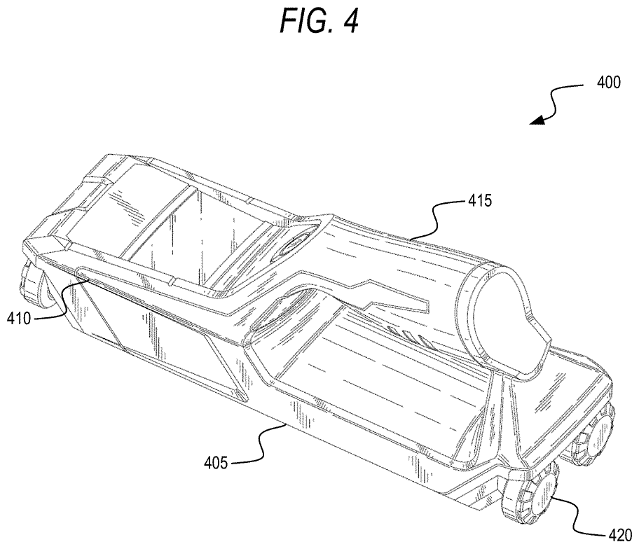

FIG. 4 illustrates a test and measurement device 400. The test and measurement device 400 includes a housing 405. The housing 405 includes an electronics housing 410 and a handle 415. The test and measurement device 400 also includes one or more wheels 420. In the illustrated embodiment, the test and measurement device 400 is a wall scanner. In other embodiments, the test and measurement device 400 can be a different test and measurement device. For example, the test and measurement device 400 can be a clamp meter, a digital multimeter, a distance meter, a fork meter, an inspection camera, a lighting tester, a temperature gun, a thermal imager, etc. Each test and measurement device 400 includes at least the housing 405 which includes graphene or a graphene polymeric material described herein.

In some embodiments, the entire housing 405 includes (e.g., is made of or to include) graphene and/or a graphene polymeric material. In other embodiments, only a portion of the housing 405 includes (e.g., is made of or to include) graphene and/or a graphene polymeric material. For example, a portion of the housing 405 in proximity to electronics within the housing 405 (see, e.g., FIG. 9). For example, one or more of the electronics housing 410 and the handle 415 includes (e.g., is made of or to include) graphene and/or a graphene polymeric material. In some embodiments, the wheels 420 includes (e.g., is made of or to include) graphene and/or a graphene polymeric material.

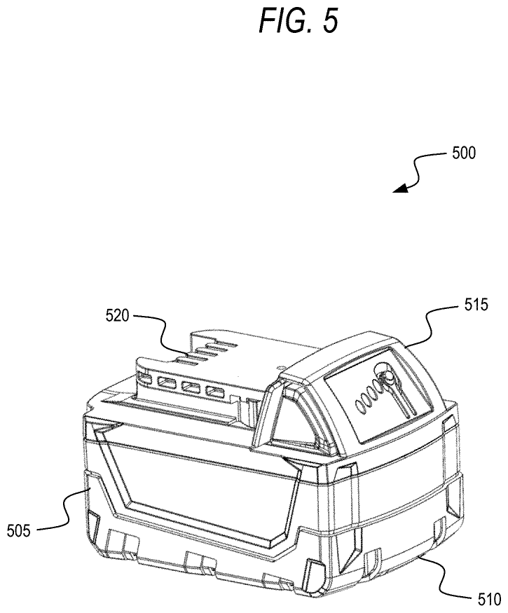

FIG. 5 illustrates a battery pack 500. The battery pack 500 includes a housing 505. The housing 505 includes an upper housing portion 510 and a lower housing portion 515. The battery pack 500 also includes a battery pack interface 520 for connecting the battery pack 500 to a device for powering the device, such as any of the devices disclosed herein. In the illustrated embodiment, the battery pack 500 is a slide-on battery pack. In other embodiments, the battery pack can be a different type of battery pack or can include a different battery pack configuration. For example, the battery pack 500 can be a battery pack having a nominal voltage of between 10V and 120V, a battery packing having a capacity of between 1.5 Amp-hours and 24 Amp-hours, a lithium-based battery pack, a lithium-polymer battery pack, a prismatic battery pack, a nickel-cadmium battery pack, a nickel-metal hydride battery pack, a battery pack including pouch battery cells, a battery pack including cylindrical battery cells, a tower or stem-type battery pack, a single cell battery pack, etc. Each battery pack 500 includes at least the housing 505 which includes graphene or a graphene polymeric material described herein.

In some embodiments, the entire housing 505 includes (e.g., is made of or to include) graphene and/or a graphene polymeric material. In other embodiments, only a portion of the housing 505 includes (e.g., is made of or to include) graphene and/or a graphene polymeric material. For example, a portion of the housing 505 in proximity to electronics within the housing 505 (see, e.g., FIG. 9). For example, one or more of the upper housing 510, the lower housing 515, and the battery pack interface 520 includes (e.g., is made of or to include) graphene and/or a graphene polymeric material.

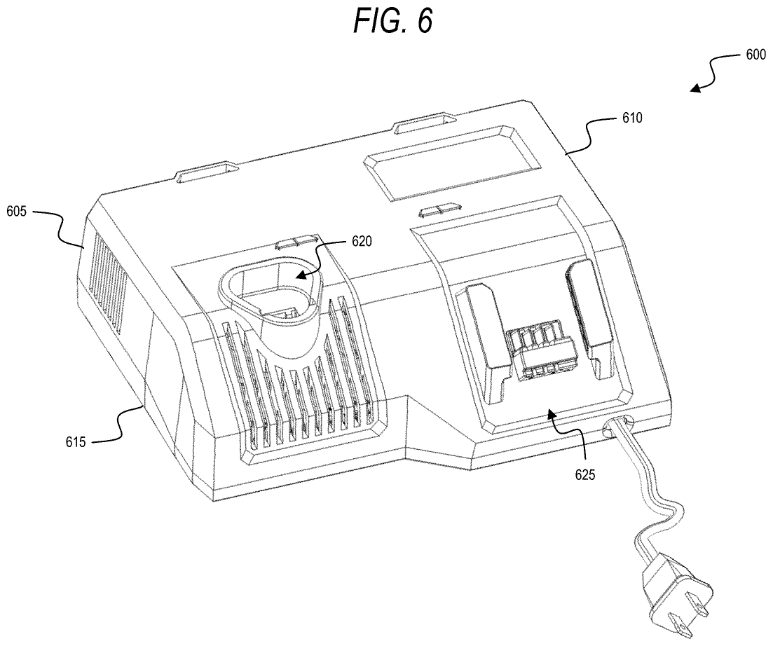

FIG. 6 illustrates a battery pack charger 600. The battery pack charger 600 includes a housing 605. The housing 605 includes an upper housing portion 610 and a lower housing portion 615. The battery pack charger 600 also includes one or more battery pack interfaces. For example, the battery pack charger includes a first battery pack interface 620 and a second battery pack interface 625. In the illustrated embodiment, the battery pack charger 600 is a dual-port charger configured to charge two different types of battery acks. In other embodiments, the battery pack charger 600 can be a different type of battery pack charger or can include a different number of battery pack interfaces. For example, the battery pack charger 600 can be a single port charger, a multi-port charger, a fast charger, a travel charger, etc. Each battery pack charger 600 includes at least the housing 605 which includes graphene or a graphene polymeric material described herein.

In some embodiments, the entire housing 605 includes (e.g., is made of or to include) graphene and/or a graphene polymeric material. In other embodiments, only a portion of the housing 605 includes (e.g., is made of or to include) graphene and/or a graphene polymeric material. For example, a portion of the housing 605 in proximity to electronics within the housing 605 (see, e.g., FIG. 9). For example, one or more of the upper housing portion 610, the lower housing portion 615, the first battery pack interface 620, and the second battery pack interface 625 includes (e.g., is made of or to include) graphene and/or a graphene polymeric material. In some embodiments, the trigger 225 includes (e.g., is made of or to include) graphene and/or a graphene polymeric material.

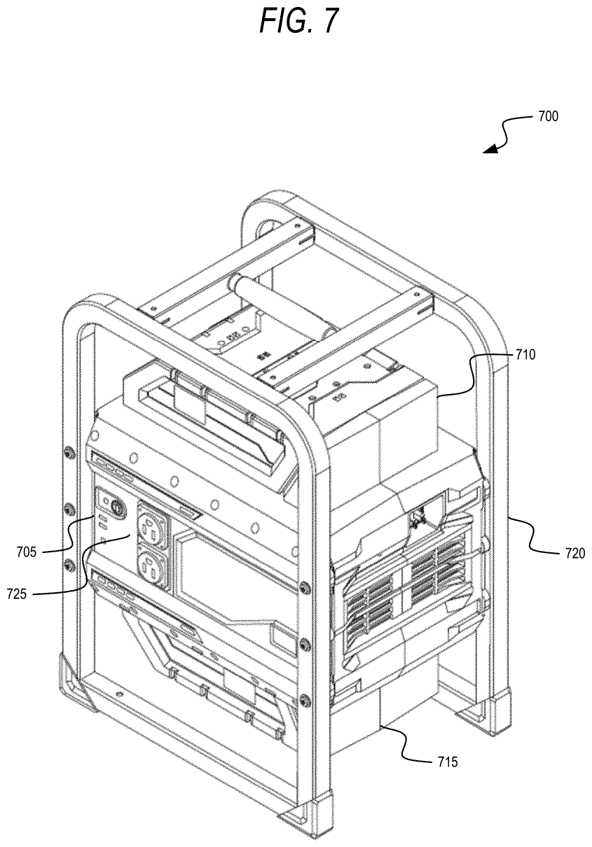

FIG. 7 illustrates a power supply or power supply device 700. The power supply device includes a housing 705. The housing 705 includes a first battery pack interface 710 and a second battery pack interface 715. The power supply device 700 also includes a frame 720 for protecting the power supply device from impact damage. The power supply device 700 also includes a power interface 725 that includes one or more alternating current power outputs and one or more direct current power outputs for powering various devices. In the illustrated embodiment, the power supply device 700 is a power source that is configured to be powered by, for example, one or more attachable battery packs. In other embodiments, the power supply device 700 can be a different type of power supply or can include a different number of battery pack interfaces. For example, the power supply device 700 can be a power supply including an internal battery core, a power supply for charging a plurality of battery packs, a power supply including an expandable battery core, etc. Each power supply device 700 includes at least the housing 705 which includes graphene or a graphene polymeric material described herein.

In some embodiments, the entire housing 705 includes (e.g., is made of or to include) graphene and/or a graphene polymeric material. In other embodiments, only a portion of the housing 705 includes (e.g., is made of or to include) graphene and/or a graphene polymeric material. For example, a portion of the housing 705 in proximity to electronics within the housing 705 (see, e.g., FIG. 9). For example, one or more of the first battery pack interface 710, the second battery pack interface 715, and the power interface 725 includes (e.g., is made of or to include) graphene and/or a graphene polymeric material. In some embodiments, the frame 720 includes (e.g., is made of or to include) graphene and/or a graphene polymeric material.

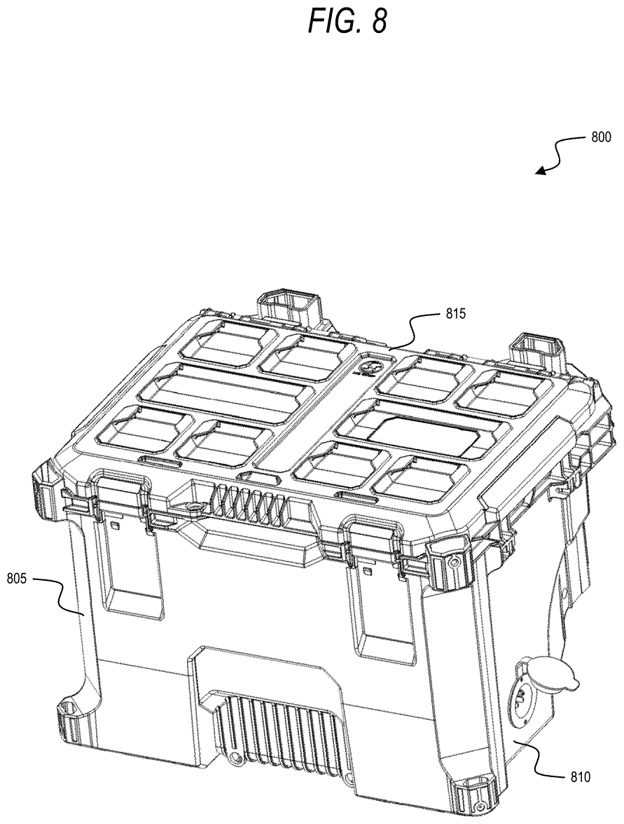

FIG. 8 illustrates a modular storage unit 800. The modular storage unit 800 includes a housing 805. The housing 805 includes a lower housing portion 810 and an upper housing portion 815. In some embodiments, the upper housing portion 815 is a lid that pivots relative to the lower housing portion 810 to open a storage area within the modular storage unit 800. In the illustrated embodiment, the modular storage unit 800 is a rectangular storage unit. In other embodiments, the modular storage unit 800 can be a different type of storage unit or can include different configuration. For example, the modular storage unit 800 can be a rolling storage unit, a toolbox, an organizer box, a cloth bag, a cooler, a heating storage unit, a cooling storage unit, a charging storage unit, etc. Each modular storage unit 800 includes at least the housing 805 which includes graphene or a graphene polymeric material described herein.

In some embodiments, the entire housing 805 includes (e.g., is made of or to include) graphene and/or a graphene polymeric material. In other embodiments, only a portion of the housing 805 includes (e.g., is made of or to include) graphene and/or a graphene polymeric material. For example, a portion of the housing 805 in proximity to electronics within the housing 805 (see, e.g., FIG. 9). For example, one or more of the lower housing portion 810 and the upper housing portion 815 includes (e.g., is made of or to include) graphene and/or a graphene polymeric material. In some embodiments, the frame 720 includes (e.g., is made of or to include) graphene and/or a graphene polymeric material.

FIG. 9 illustrates an electronics or control system for a device. The device can be any of the devices disclosed herein, such as the power tool 100, the outdoor power equipment 200, the lighting device 300, the test and measurement device 400, the battery pack 500, the battery pack charger 600, the power supply device 700, or the modular storage unit 800. The control system can be modified as required for each device. For example, the battery pack 500 would include a bank of battery cells that would provide a power output to an interface of the battery pack 500. The power tool 100 would include, for example, a motor. The lighting device 300 would include, for example, one or more light outputs. The control system has been generalized for descriptive purposes. However, each device disclosed herein can include some electronics, such as the control electronics illustrated in FIG. 9. The control system includes a controller 900. The controller 900 is electrically and/or communicatively connected to a variety of modules or components of the device. For example, the illustrated controller 900 is connected to an actuator 905 (e.g., a trigger, an ON/OFF switch, etc.) which is connected to an actuator switch 910 (e.g., for providing a signal to the controller 900). The device also includes a battery pack interface 915 for connecting the device to a battery pack. For the battery pack 500, the battery pack interface 915 could be configured as a power input (for charging) or a power output (for powering another device). The controller 900 is also connected to an output unit 920 (e.g., a motor, a light, a display, a power output, a charging interface, etc.) through a power output module 925 (e.g., to enable or disable the output unit). The controller 900 is also connected to one or more sensors 930 (e.g., voltage sensors, current sensors, temperature sensors, motion sensors (e.g., accelerometers, gyroscopes, inertial measurement units, etc.), one or more indicators 935, a user input or user input module 940, and a power input module 945. The controller 900 includes combinations of hardware and software that are operable to, among other things, control the operation of the device, monitor a condition of the device, enable, or disable operation of the device, etc.

The controller 900 includes a plurality of electrical and electronic components that provide power, operational control, and protection to the components and modules within the controller 900 and/or the device. For example, the controller 900 includes, among other things, a processing unit 950 (e.g., a microprocessor, a microcontroller, an electronic processor, an electronic controller, or another suitable programmable device), a memory 955, input units 960, and output units 965. The processing unit 950 includes, among other things, a control unit 970, an arithmetic logic unit (“ALU”) 975, and a plurality of registers 980 (shown as a group of registers in FIG. 9) and is implemented using a known computer architecture (e.g., a modified Harvard architecture, a von Neumann architecture, etc.). The processing unit 950, the memory 955, the input units 960, and the output units 965, as well as the various modules or circuits connected to the controller 900 are connected by one or more control and/or data buses (e.g., common bus 985). The control and/or data buses are shown generally in FIG. 9 for illustrative purposes. The use of one or more control and/or data buses for the interconnection between and communication among the various modules, circuits, and components would be known to a person skilled in the art in view of the invention described herein.

The memory 955 is a non-transitory computer readable medium and includes, for example, a program storage area and a data storage area. The program storage area and the data storage area can include combinations of different types of memory, such as a ROM, a RAM (e.g., DRAM, SDRAM, etc.), EEPROM, flash memory, a hard disk, an SD card, or other suitable magnetic, optical, physical, or electronic memory devices. The processing unit 950 is connected to the memory 955 and executes software instructions that are capable of being stored in a RAM of the memory 955 (e.g., during execution), a ROM of the memory 955 (e.g., on a generally permanent basis), or another non-transitory computer readable medium such as another memory or a disc. Software included in the implementation of the device can be stored in the memory 955 of the controller 900. The software includes, for example, firmware, one or more applications, program data, filters, rules, one or more program modules, and other executable instructions. The controller 900 is configured to retrieve from the memory 955 and execute, among other things, instructions related to the control processes and methods for the device. In other constructions, the controller 900 includes additional, fewer, or different components.

The battery pack interface 915 includes a combination of mechanical components (e.g., rails, grooves, latches, etc.) and electrical components (e.g., one or more terminals) configured to and operable for interfacing (e.g., mechanically, electrically, and communicatively connecting) the device with another device (e.g., a battery pack, etc.). The battery pack interface 915 is also configured to communicatively connect to the controller 900 via a communications line 990.

The indicators 935 include, for example, one or more light-emitting diodes (“LEDs”). The indicators 935 can be configured to display conditions of, or information associated with, the device. For example, the indicators 935 are configured to indicate measured electrical characteristics of the device, the status of the device, etc.

The user input module 940 is operably coupled to the controller 900 to, for example, select a mode of operation of the device, a torque and/or speed setting for the device (e.g., using torque and/or speed switches), etc. In some embodiments, the user input module 940 includes a combination of digital and analog input or output devices required to achieve a desired level of operation for the device, such as one or more knobs, one or more dials, one or more switches, one or more buttons, a touchscreen display, etc.

The electronics illustrated and described with respect to FIG. 9 can radiate emissions that will be attenuated by the housings of the devices. This phenomenon is observed because the housings of the devices, or at least a portion of the housings of the devices, include graphene or graphene polymeric materials according to the present disclosure.

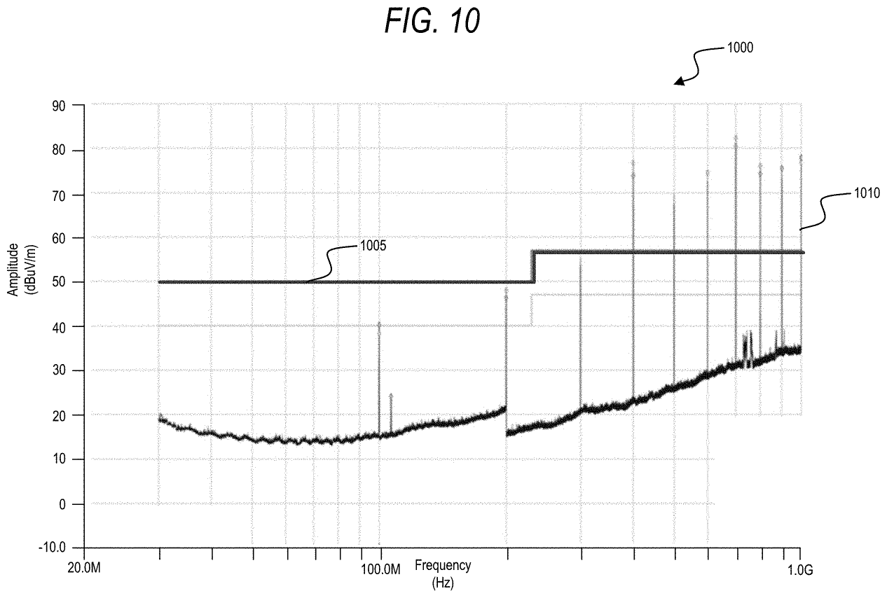

FIG. 10 illustrates radiated emission signature 1000 for a device with no graphene-based shielding in place (e.g., no graphene or graphene polymeric materials impregnated in the housing of the device).

TABLE 1
EMISSION DATA FOR UNSHIELDED DEVICE

| Frequency | | Peak | Correction | Peak | Peak |
|---|---|---|---|---|---|
| (MHz) | Limit | (Raw) | Factor | (Corrected) | (Margin) |
| 30.300 | 50.00 | 30.74 | −11.15 | 19.58 | 30.42 |
| 99.990 | 50.00 | 51.75 | −13.57 | 38.19 | 11.81 |
| 199.979 | 50.00 | 58.90 | −10.99 | 47.91 | 2.09 |
| 400.010 | 57.00 | 80.84 | −4.22 | 76.61 | −19.61 |
| 599.990 | 57.00 | 72.79 | 1.65 | 74.43 | −17.43 |
| 699.990 | 57.00 | 77.48 | 4.78 | 82.26 | −25.26 |
| 800.010 | 57.00 | 70.05 | 5.92 | 75.97 | −18.97 |
| 999.990 | 57.00 | 67.30 | 9.46 | 76.76 | −19.76 |

A test limit 1005 can be used to evaluate how effectively the device is shielded. As illustrated in FIG. 10, several emissions peaks 1010 at different frequencies are shown to exceed the test limit 1005.

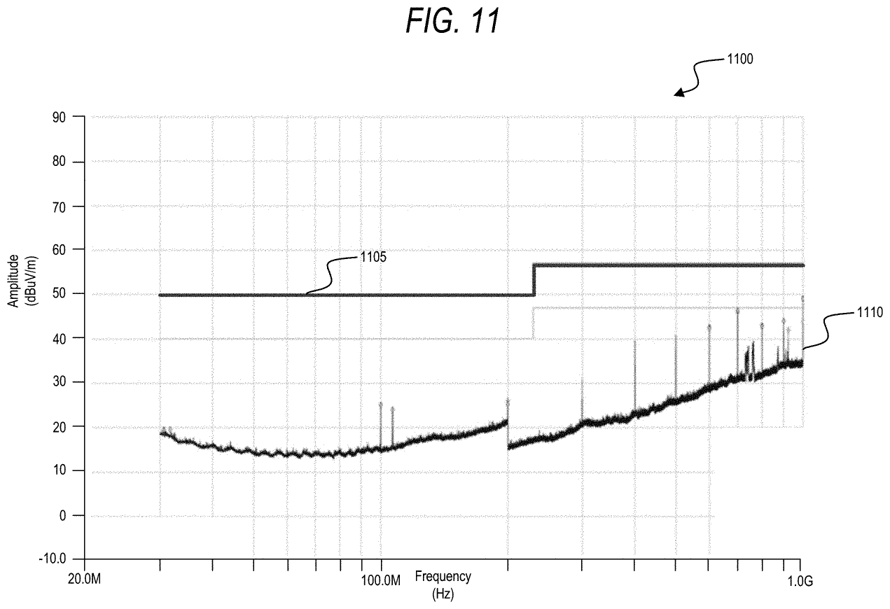

FIG. 11 illustrates radiated emission signature 1100 for a device with graphene-based shielding in place (e.g., graphene or graphene polymeric materials impregnated in the housing of the device).

TABLE 2
EMISSION DATA FOR GRAPHENE SHIELDED DEVICE

| Frequency | | Peak | Correction | Peak | Peak |
|---|---|---|---|---|---|
| (MHz) | Limit | (Raw) | Factor | (Corrected) | (Margin) |
| 31.740 | 50.00 | 31.06 | −11.52 | 19.54 | 30.46 |
| 199.979 | 50.00 | 37.03 | −10.99 | 26.04 | 23.96 |
| 599.990 | 50.00 | 41.04 | 1.65 | 42.68 | 14.32 |
| 699.990 | 57.00 | 41.35 | 4.78 | 46.13 | 10.87 |
| 800.010 | 57.00 | 37.11 | 5.92 | 43.03 | 13.97 |
| 922.980 | 57.00 | 33.21 | 8.72 | 41.93 | 15.07 |
| 999.990 | 57.00 | 34.36 | 9.46 | 43.82 | 13.18 |

A test limit 1105 can be used to evaluate how effectively the device is shielded. As illustrated in FIG. 11, no emissions peaks 1110 at any tested frequencies are shown to exceed the test limit 1105.

Devices, methods, articles of manufacture, and materials in accordance with the present disclosure may take any one or more of the following configurations:
(1) A graphene polymeric material, the graphene polymeric material comprising: graphene; and a polymer, wherein the polymer is impregnated with the graphene; and wherein the graphene polymeric material attenuates radiated emissions, and prevents electrostatic charge accumulation.
(2) The graphene polymeric material of (1), wherein the polymer is a thermoplastic polymer.
(3) The graphene polymeric material of (1) or (2), wherein the thermoplastic polymer comprises at least one polymer selected from the group consisting of polyvinyl chloride, polycarbonate, acrylonitrile butadiene styrene, polyamide, polypropylene, and high-density polyethylene.
(4) The graphene polymeric material of (1) or (2), wherein the thermoplastic polymer is a thermoplastic polyurethane polymer.
(5) The graphene polymeric material of any one of (1)-(4), wherein the graphene polymeric material comprises 50 wt % to 99 wt % polymer and 1 wt % to 50 wt % graphene.
(6) The graphene polymeric material of any one of (1)-(5), wherein the graphene polymeric material is in the form of pellets.
(7) A housing comprising the graphene polymeric material of any one of (1)-(6).
(8) A method of forming an article of manufacture from a graphene polymeric material, the method comprising: providing a graphene polymeric material comprising graphene impregnated within a polymer; and forming the article of manufacture from the graphene polymeric material.
(9) The method of (8), wherein the providing the graphene polymeric material includes injecting the graphene polymeric material into a mold.
(10) The method of (8) or (9), wherein the forming the article of manufacture is via injection molding.
(11) The method of any one of (8)-(10), wherein the formed article of manufacture is a housing.
(12) The method of any one of (8)-(11), wherein the formed article of manufacture attenuates electromagnetic radiation.
(13) The method of any one of (8)-(12), wherein the formed article of manufacture prevents electrostatic charge accumulation.
(14) A device including a housing, the housing comprising: a graphene polymeric material, the graphene polymeric material comprising: graphene; and a polymer, wherein the polymer is impregnated with the graphene; and wherein the graphene polymeric material attenuates radiated emissions, and prevents electrostatic charge accumulation.
(15) The device of (14), wherein the device is a power source.
(16) The device of (15), wherein the device is a battery pack or battery pack charger.
(17) The device of (14), wherein the device is a power tool.
(18) The device of (14), wherein the device is a piece of outdoor power equipment.
(19) The device of (14), wherein the device is a vacuum cleaner.
(20) The device of any one of (14)-(19), wherein the device attenuates radiated emissions.

Thus, embodiments described herein provide, among other things, devices that include housings or housing structures that include graphene and/or a graphene polymeric material. Various features and advantages are set forth in the following claims.

What is claimed is:

1. A graphene polymeric material, the graphene polymeric material comprising:
graphene; and
a polymer,
wherein the polymer is impregnated with the graphene; and
wherein the graphene polymeric material attenuates radiated emissions, and prevents electrostatic charge accumulation.

2. The graphene polymeric material of claim 1, wherein the polymer is a thermoplastic polymer.

3. The graphene polymeric material of claim 2, wherein the thermoplastic polymer comprises at least one polymer selected from the group consisting of polyvinyl chloride, polycarbonate, acrylonitrile butadiene styrene, polyamide, polypropylene, and high-density polyethylene.

4. The graphene polymeric material of claim 2, wherein the thermoplastic polymer is a thermoplastic polyurethane polymer.

5. The graphene polymeric material of claim 1, wherein the graphene polymeric material comprises 50 wt % to 99 wt % polymer and 1 wt % to 50 wt % graphene.

6. The graphene polymeric material of claim 1, wherein the graphene polymeric material is in the form of pellets.

7. A housing comprising the graphene polymeric material of claim 1.

8. A method of forming an article of manufacture from a graphene polymeric material, the method comprising:
providing a graphene polymeric material comprising graphene impregnated within a polymer; and
forming the article of manufacture from the graphene polymeric material.

9. The method of claim 8, wherein the providing the graphene polymeric material includes injecting the graphene polymeric material into a mold.

10. The method of claim 8, wherein the forming the article of manufacture is via injection molding.

11. The method of claim 8, wherein the formed article of manufacture is a housing.

12. The method according to claim 8, wherein the formed article of manufacture attenuates electromagnetic radiation.

13. The method according to claim 8, wherein the formed article of manufacture prevents electrostatic charge accumulation.

14. A device including a housing, the housing comprising:
a graphene polymeric material, the graphene polymeric material comprising:
graphene; and
a polymer,
wherein the polymer is impregnated with the graphene; and
wherein the graphene polymeric material attenuates radiated emissions, and prevents electrostatic charge accumulation.

15. The device of claim 14, wherein the device is a power source.

16. The device of claim 15, wherein the device is a battery pack or battery pack charger.

17. The device of claim 14, wherein the device is a power tool.

18. The device of claim 14, wherein the device is a piece of outdoor power equipment.

19. The device of claim 14, wherein the device is a vacuum cleaner.

20. The device of claim 14, wherein the device attenuates radiated emissions.
